(19) United States
(12) Patent Application Publication
(10) Pub. No.: US 2024/0006502 A1
(43) Pub. Date: Jan. 4, 2024

(54) FIELD EFFECT TRANSISTORS WITH 2-DIMENSIONAL ELECTRON GAS CHANNELS

(71) Applicant: INTERNATIONAL BUSINESS MACHINES CORPORATION, Armonk, NY (US)

(72) Inventors: Julien Frougier, Albany, NY (US); Kangguo Cheng, Schenectady, NY (US); Ruilong Xie, Niskayuna, NY (US); Juntao Li, Cohoes, NY (US); Chanro Park, Clifton Park, NY (US); Oleg Gluschenkov, Tannersville, NY (US)

(21) Appl. No.: 17/856,602

(22) Filed: Jul. 1, 2022

(51) Int. Cl. H01L 29/423; H01L 29/20; H01L 29/778; H01L 29/786; H01L 29/66; H01L 21/8238

(52) U.S. Cl. CPC H01L 29/42392; H01L 29/2003; H01L 29/7788; H01L 29/78618; H01L 21/823807; H01L 29/6656; H01L 29/66742; H01L 21/823814; H01L 29/78696

(57) ABSTRACT

A semiconductor structure that includes a channel region comprising vertically stacked channels of at least two III-V semiconductor material layers having a two dimensional electron gas regions at an interface of the at least two III-V semiconductor material layers; a gate all around (GAA) geometry gate structure present on the channel region; and source and drain regions on opposing sides of the channel region.

### BACKGROUND

The present disclosure relates to semiconductor devices, and more particularly to devices composed of III-V field effect transistors having two-dimensional electron gas (2-DEG) channels for high power systems.

With the continuing trend towards miniaturization of integrated circuits (ICs), there is a need for transistors to have higher drive currents with increasingly smaller dimensions. Efficient high power distribution systems are desired for heterogenous integration fabrication for providing high to low voltage conversion. Single stage converters can provide lower power loss, high efficiency and a wide load range. Gallium nitride (GaN) Complementary Metal Oxide Semiconductor (CMOS) platforms have been designed as a good candidate to provide further enhancements in the efficiency of single stage converters, and can provide reduced circuit complexity.

### SUMMARY

In one aspect, the present disclosure provides a semiconductor structure that includes a channel region including at least one channel of at least two III-V semiconductor material layers having a two dimensional electron gas (2DEG) regions at an interface of the at least two III-V semiconductor material layers. In some embodiments, the semiconductor structure includes a gate all around (GAA) geometry gate structure present on the channel region. In some embodiments, the semiconductor structure also includes source and drain regions on opposing sides of the channel region.

In another embodiment, the semiconductor structure includes a channel region that includes at least one channel of at least two III-V semiconductor material layers having a two dimensional electron gas regions at an interface of the at least two III-V semiconductor material layers. The at least two III-V semiconductor material layers include a core semiconductor layer and a wrap around semiconductor layer that is present on the exterior faces of the core semiconductor layer. The semiconductor structure can also include a gate all around (GAA) geometry gate structure present on the channel region; and source and drain regions on opposing sides of the channel region.

In another aspect of the present disclosure, a method of forming a semiconductor structure is described that includes forming a stack including a repeating sequence including a sacrificial III-V semiconductor material and at least two channel III-V semiconductor materials that form a two dimensional electron gas region at an interface of the at least two channel III-V semiconductor materials. In a following step, a replacement gate structure is formed on a channel region of a fin structure including the stack including the repeating sequence including a sacrificial III-V semiconductor material and at least two channel III-V semiconductor materials; and III-V source and drain regions are formed on source and drain portions of the fin structure at opposing ends of the channel region. The method can continue with removing the sacrificial III-V semiconductor material, and replacing the replacement gate structure with a functional gate structure having a gate all around (GAA) geometry on the at least two channel III-V semiconductor materials having the two dimensional electron gas region at the interface of the at least two channel III-V semiconductor materials.

In another embodiment of the present disclosure, a method of forming a semiconductor structure is described that includes forming a stack including a repeating sequence including a sacrificial III-V semiconductor material and a III-V core semiconductor material. In a following step, a replacement gate structure is formed on a channel region of a fin structure including the stack including the repeating sequence including the sacrificial III-V semiconductor material and the III-V core semiconductor material; and III-V source and drain regions are formed on source and drain portions of the fin structure at opposing ends of the channel region. The replacement gate structure is then removed. The method can continue with removing the sacrificial III-V semiconductor material. Thereafter, the III-V core semiconductor material is trimmed and a III-V cladded epitaxial material is formed on exterior surfaces of the III-V core semiconductor material that is trimmed. A two dimensional electron gas region is present at an interface of the III-V core semiconductor material and the III-V cladded epitaxial material. A replacement gate structure with a functional gate electrode having a gate all around (GAA) geometry is formed on the channel region including the two dimensional electron gas region is present at an interface of the III-V core semiconductor material and the III-V cladded epitaxial material.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a top down view illustrating semiconductor devices suitable for a gallium nitride (GaN) n-type semiconductor device with a gate all around (GAA) gate structure and a fully depleted two dimensional (2D) electron gas (EG) channel, in accordance with one embodiment of the present disclosure.

FIG. 2A is a side cross-sectional view along section line A-A of FIG. 1 illustrating an along the channel cross-section of the structure depicted in FIG. 1.

FIG. 2B is a side cross-sectional view along section line B-B of FIG. 1 illustrating an across the channel cross-section of the structure depicted in FIG. 1, in which the channel configuration is of a stacked planar two dimensional (2D) electron gas (EG) channel.

FIG. 3A is a side cross-sectional view along section line A-A of FIG. 1 illustrating an along the channel cross-section of the structure depicted in FIG. 1, in which the channel configuration is of a wrap around two dimensional (2D) electron gas (EG) channel.

FIG. 3B is a side cross-sectional view along section line B-B of FIG. 1 illustrating an across the channel cross-section of the structure depicted in FIG. 1, in which the channel configuration is of a wrap around two dimensional (2D) electron gas (EG) channel.

FIG. 4 is a side cross-sectional view of a stack of III-V semiconductor material layers atop a supporting substrate.

FIG. 5A is a side cross-sectional view along the channel cross-section of the structure illustrating forming fin structures from the stack depicted in FIG. 4.

FIG. 5B is a side cross-sectional view illustrating an across the channel cross-section of the structure depicted in FIG. 5A, and within the gate structure.

FIG. 5C is a side cross-sectional view that is parallel to the cross-section direction depicted in FIG. 5B, but it taken from a portion of the device outside the channel and gate structure regions and through the source and drain regions.

FIG. 6A is a side cross-sectional view along the channel cross-section of the structure illustrating a resultant structure following a process sequence that is applied to the structure depicted in FIGS. 5A-5C that includes forming a dummy oxide layer, forming a dummy gate on the dummy oxide layer, forming a spacer on the dummy gate, and then performing a fin recess step, in accordance with one embodiment of the present disclosure.

FIG. 6B is a side cross-sectional view illustrating an across the channel cross-section of the structure depicted in FIG. 6A, and within the gate structure.

FIG. 6C is a side cross-sectional view that is parallel to the cross-section depicted in FIG. 6B, but it taken from a portion of the device outside the channel and gate structure regions and through the source and drain regions.

FIG. 7A is a side cross-sectional view depicting forming an inner spacer in the stack of channel material layers, in accordance with one embodiment of the present disclosure.

FIG. 7B is a side cross-sectional view illustrating an across the channel cross-section of the structure depicted in FIG. 7A, and within the gate structure.

FIG. 7C is a side cross-sectional view that is parallel to the cross section depicted in FIG. 7B, but it taken from a portion of the device outside the channel and gate structure regions and through the source and drain regions.

FIG. 8A is a side cross-sectional view depicting one embodiment of forming source/drain regions from epitaxially grown semiconductor materials.

FIG. 8B is a side cross-sectional view illustrating an across the channel cross-section of the structure depicted in FIG. 8A, and within the gate structure.

FIG. 8C is a side cross-sectional view that is parallel to the cross-section depicted in FIG. 8B, but it taken from a portion of the device outside the channel and gate structure regions and through the source and drain regions.

FIG. 9A depicts a side cross-sectional view of removing the dummy gate electrode and the dummy oxide layer, in accordance with one embodiment of the present disclosure.

FIG. 9B is a side cross-sectional view illustrating an across the channel cross-section of the structure depicted in FIG. 9A, and within the gate structure.

FIG. 9C is a side cross-sectional view that is parallel to the cross-section direction depicted in FIG. 9B, but it taken from a portion of the device outside the channel and gate structure regions and through the source and drain regions.

FIG. 10A is a side cross-sectional view depicts one embodiment of forming a functional gate structure in the opening that is formed by removing the dummy gate electrode, the dummy oxide layer and the sacrificial III-V semiconductor material.

FIG. 10B is a side cross-sectional view illustrating an across the channel cross-section of the structure depicted in FIG. 10A, and within the gate structure.

FIG. 10C is a side cross-sectional view that is parallel to the cross-section depicted in FIG. 10B, but it taken from a portion of the device outside the channel and gate structure regions and through the source and drain regions.

FIG. 11A is a side cross-sectional view that depicts a process step of another embodiment of the present disclosure for forming the structures depicted in FIGS. 3A-3B, which includes removing the first III-V semiconductor material layer selectively to the second III-V semiconductor material layer.

FIG. 11B is a side cross-sectional view illustrating an across the channel cross-section of the structure depicted in FIG. 11A, and within the gate structure.

FIG. 11C is a side cross-sectional view that is parallel to the cross-section depicted in FIG. 11B, but it taken from a portion of the device outside the channel and gate structure regions and through the source and drain regions.

FIG. 12A is a side cross-sectional view illustrating trimming the first III-V semiconductor material layers that remain suspended.

FIG. 12B is a side cross-sectional view illustrating an across the channel cross section of the structure depicted in FIG. 11A, and within the gate structure.

FIG. 12C is a side cross-sectional view that is parallel to the cross section depicted in FIG. 12B, but it taken from a portion of the device outside the channel and gate structure regions.

FIG. 13A is a side cross-sectional view illustrating the formation of a wrap around III-V semiconductor layer on the trimmed first III-V semiconductor material layer.

FIG. 13B is a side cross-sectional view illustrating an across the channel cross-section of the structure depicted in FIG. 13A, and within the gate structure.

FIG. 13C is a side cross-sectional view that is parallel to the cross-section direction depicted in FIG. 13B, but it taken from a portion of the device outside the channel and gate structure regions and through the source and drain regions.

FIG. 14A is a side cross sectional view that depicts one embodiment of forming a functional gate structure in the opening illustrated in FIGS. 13A-13C that is formed by removing the dummy gate electrode, the dummy oxide layer and the sacrificial III-V semiconductor material.

FIG. 14B is a side cross-sectional view illustrating an across the channel cross-section of the structure depicted in FIG. 14A, and within the gate structure.

FIG. 14C is a side cross-sectional view that is parallel to the cross-section depicted in FIG. 14B, but it taken from a portion of the device outside the channel and gate structure regions and through the source and drain regions.

### DETAILED DESCRIPTION OF PREFERRED EMBODIMENTS

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

It has been determined that development of efficient gallium nitride (GaN) complementary metal oxide semiconductor (CMOS) technology would benefit from development of gallium nitride (GaN) hole channel field effect transistors (FETs). Some challenges to developing gallium nitride (GaN) hole channel field effect transistors (FETs) include low hole mobility. For example, prior demonstration have been reported with hole mobilities ranging from 10 to 20 cm²/V for a reasonable charge density.

It has been determined that there is a need to increase the dopant ionization efficiency further to improve the carrier density without affecting the carriers' mobility. The state of the art devices still exhibit performance limitations linked to insufficient charge density, mobility and inadequate gate control.

In some embodiments, the methods and structures of the present disclosure can overcome at least some of the aforementioned difficulties in by employing a stacked gate all around (GAA) architecture with fully depleted two dimensional (2D) electron gas (EG) channel to improve the charge density and the gate control.

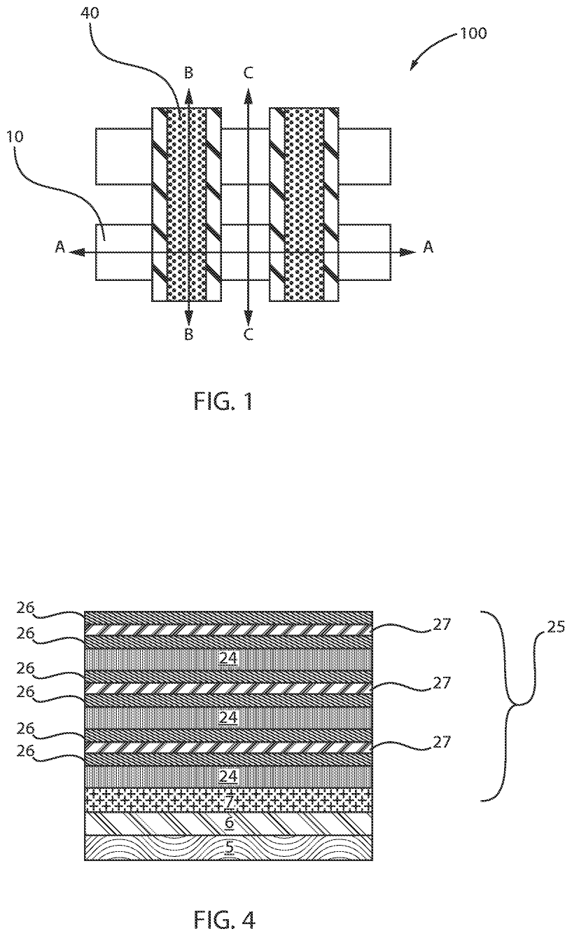

The structures and methods of the present disclosure are now described with reference to FIGS. 1-14C.

FIGS. 1-3B depict some embodiments of a gate all around (GAA) field effect transistor (FET) with a stacked two dimensional (2D) electron gas (EG) channel. Broadly, the structures of the present disclosure are field effect transistors (FETs) 100 that can include a source/drain regions 10, a gate region 15 (also referred to as gate structure) between the source/drain regions, and the two dimensional electron gas (2DEG) channel 20. A field effect transistor (FET) is a semiconductor device in which output current, i.e., source-drain current, is controlled by the voltage applied to a gate structure 15 to the semiconductor device. A “field effect transistor” has three terminals, i.e., gate structure, source region and drain region. As used herein, the term “drain” means a doped region in semiconductor device located at the end of the channel region, in which carriers are flowing out of the transistor through the drain. The term “source” is a doped region in the semiconductor device, in which majority carriers are flowing into the channel region.

The channel of the semiconductor device structures that are disclosed herein are 2DEG channels 20. In some examples, a 2DEG channel includes at least one layer of electrons found in MOSFETs (metal-oxide-semiconductor field-effect transistors) that is proximate to a dielectric layer, e.g., gate oxide. In these examples, when the transistor is in inversion mode, the electrons underneath the gate oxide are confined to the semiconductor-oxide interface, and thus occupy well defined energy levels. For thin-enough potential wells and temperatures not too high, only the lowest level is occupied (see the figure caption), and so the motion of the electrons perpendicular to the interface can be ignored. However, the electron is free to move parallel to the interface, and so is quasi-two-dimensional.

It is noted that for N-type transistors, electrons are the carriers for the current so that the term 2-Dimensional Electron Gas (2-DEG) is technically accurate. However, for P-type transistors, the carriers for the current are holes. For a P-type transistor, the term 2-Dimensional Electron Gas (2-DEG) is technically inaccurate due to the current carriers being a hole, as opposed to an electron. For a P-type transistor, a more technically accurate designation is 2-Dimensional Hole Gas (2-DHG) for a P-type channel structure exhibiting the same characteristics for an N-type transistor with a 2-DEG channel region. However, in the present disclosure, the term “2-Dimensional Electron Gas (2-DEG)” is intended to cover the scenario for when the charge carriers are both electrons and holes for their respective N-type and P-type transistors. This definition is applicable so long as the specification and claims do not make a specific distinction to N-type and P-type channel regions.

2DEGs can also include high-electron-mobility-transistors (HEMTs) and rectangular quantum wells. HEMTs are field-effect transistors that utilize the heterojunction between two semiconducting materials to confine electrons to a triangular quantum well. Electrons confined to the heterojunction of HEMTs exhibit higher mobilities than those in MOSFETs, since the former device utilizes an intentionally undoped channel thereby mitigating the deleterious effect of ionized impurity scattering. Two closely spaced heterojunction interfaces may be used to confine electrons to a rectangular quantum well.

In the present case, the 2DEG channel 20 is present between two layers of semiconductor material. For example, the semiconductor material may be a III-V semiconductor material. By “III-V semiconductor material” it is meant that the semiconductor material includes at least one element from Group III (i.e., Group 13) of the Periodic Table of Elements and at least one element from Group V (i.e., Group 15) of the Periodic Table of Elements. In some embodiments, the fin structures provided by the methods and structures of the present disclosure are composed of epitaxially semiconductor materials that have low defect density. In some embodiments, the structures and methods described herein can employ a stacked gate all around (GAA) architecture. In some embodiments, the use of the gate all around (GAA) architecture in combination with a fully depleted two dimensional electron gas (2DEG) can improve charge density and gate control.

When referring to “full depleted” it is meant that the entire 2DEG surface is made conductive when a gate voltage is applied rather than only the sides of the channel regions where the 2DEG is directly against the gate structure. This is made possible by the use of thin epitaxial layers for the channel regions allowing the electric field generated by the gate to reach the entire surface of the 2DEG regions.

As noted, at least one channel is composed of a III-V material, such as gallium nitride (GaN). In some embodiments, the two dimensional electron gas (2DEG) is present in contact with at least one side, and in some instances both sides, of the III-V material that provides the channel. For example, the two dimensional gas (2DEG) regions are formed at the interface of two III-V semiconductor materials, e.g., gallium nitride containing materials, such as gallium nitride (GaN), and aluminum gallium nitride (AlGaN). In some instances, the channel of the gate region has III-V material wrapped around and in contact with the two dimensional electron gas (2DEG) regions.

The use of the gate all around (GAA) architecture in combination with a fully depleted two dimensional electron gas (2DEG) can improve charge density and gate control for III-V hole channel FETs (e.g., p-type FET including GaN material channel). For example, the GAA architecture with fully depleted two dimensional electron gas (2DEG) can advantageously provide for increased ionization efficiency and higher carrier densities without negatively affecting, i.e., decreasing, carrier mobility.

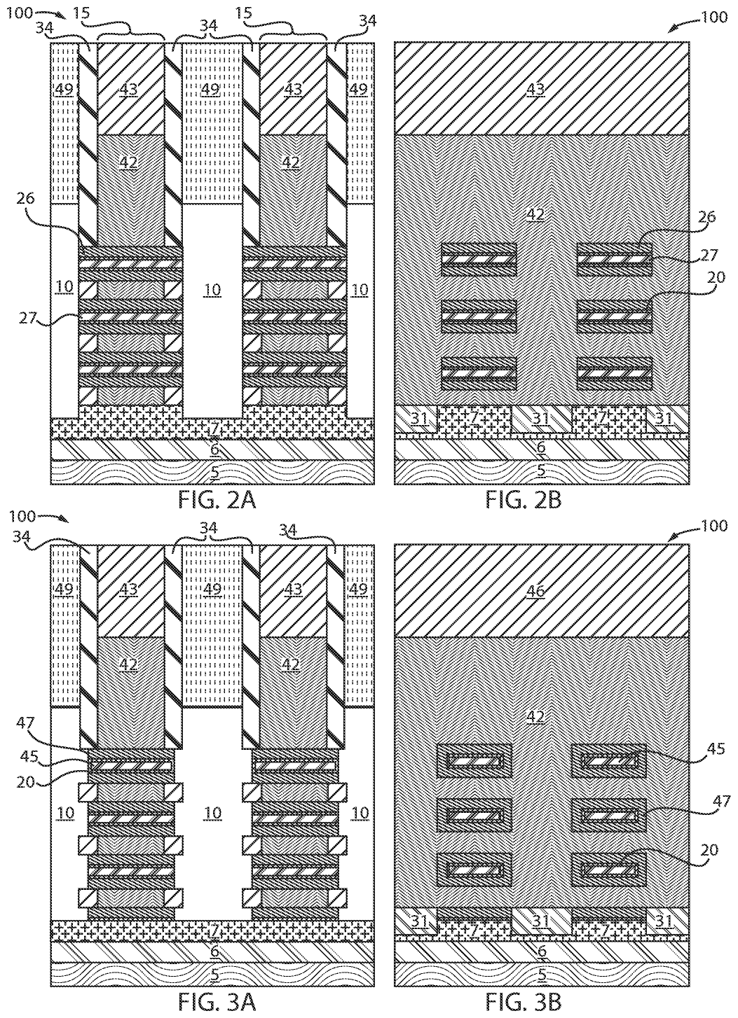

FIGS. 2A and 2B illustrate one embodiment of gate all around (GAA) architecture in combination with a fully depleted two dimensional electron gas (2DEG) regions, in which the channel configuration is of a stacked planar two dimensional (2D) electron gas (EG) channel.

FIGS. 3A and 3B illustrate another embodiment of gate all around (GAA) architecture in combination with a fully depleted two dimensional electron gas (2DEG) regions, in which the channel configuration is of a wrap around two dimensional (2D) electron gas (EG) channel. In one embodiment, the semiconductor structure includes a channel region that includes vertically stacked channels of at least two III-V semiconductor material layers having a two dimensional electron gas regions 20 at an interface of the at least two III-V semiconductor material layers. The at least two III-V semiconductor material layers include a core semiconductor layer 45 and a wrap around semiconductor layer 47 that is present on the exterior faces of the core semiconductor layer 45. The semiconductor structure can also include a gate all around (GAA) geometry gate structure present on the channel region; and source and drain regions on opposing sides of the channel region.

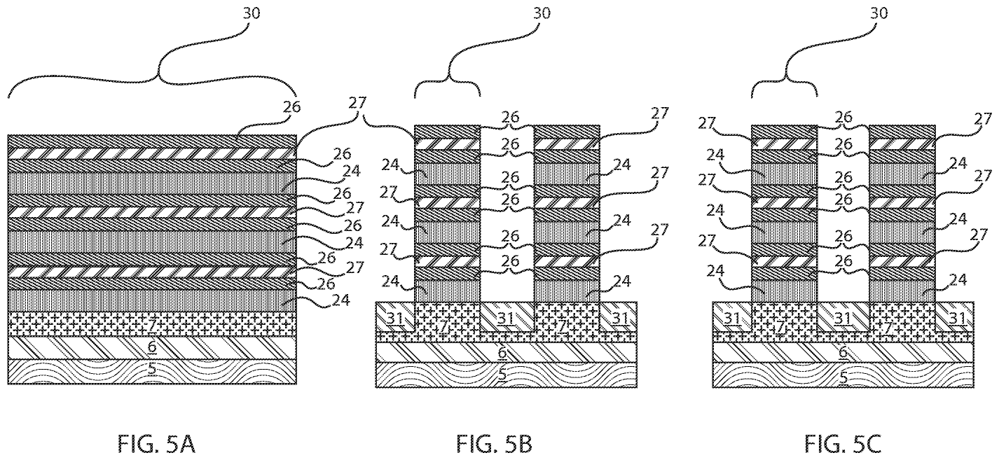

FIGS. 4-11C illustrate some embodiments for forming the structures depicted in FIGS. 1-2B. FIG. 4 illustrates one embodiment of a stack 25 of III-V semiconductor material layers atop a supporting substrate 21. FIG. 4 illustrates a cross-section from any of section lines A-A, B-B and C-C from the final structure. The section lines are illustrated in FIG. 1, which is a top down view. Section line A-A provides a cross-sectional along the channel, i.e., in a direction extending from the source region to the drain region of the device. Section line B-B provides a cross-section across the channel of the device. Section line B-B is perpendicular to section line A-A and is present through the gate structure of the device. Section line C-C is parallel to section line B-B, but is not present through the gate structure. Section line C-C is present through the source/drain region of the device. In the descriptions of FIGS. 5A-14C, the figures having designation “A” are cross-sections along section line A-A, the figures having designation “B” are cross-sections along section line B-B, and the figures having designation “C” are cross-sections along section line C-C.

Referring to FIG. 4, the supporting substrate 5 may be composed of a type IV semiconductor material, such as silicon. In one example, the supporting substrate 5 may be silicon having a <111> crystal orientation. In some embodiments, a buffer layer 6 may be present atop the supporting substrate 5. The buffer layer 6 may be formed using a deposition process, e.g., chemical vapor deposition, epitaxial growth etc. This can be composed of gallium nitride (GaN). The buffer layer 6 may have a thickness ranging from 3 microns to 10 microns. The term “epitaxial semiconductor material” denotes a semiconductor material that has been formed using an epitaxial deposition or growth process. “Epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

In some embodiments, an undoped GaN or unintentionally doped GaN (UID-GaN) layer 7 may be present atop the buffer layer 6. The undoped GaN or unintentionally doped GaN (UID-GaN) layer 7 may be used to suppress the occurrence of 2DEG degradation in AlGaN/GaN heterostructures on silicon substrates. In one example, the undoped GaN or unintentionally doped GaN (UID-GaN) layer 7 may be composed of gallium nitride (GaN) and have a nanoscale thickness. For example, the thickness of the gallium nitride (GaN) layer may range from 100 nm to 400 nm. The undoped GaN or unintentionally doped GaN (UID-GaN) layer 7 may also be formed using a deposition process, such as chemical vapor deposition (CVD) and/or epitaxial growth.

In some embodiments, the buffer layer 6 and the undoped GaN or unintentionally doped GaN (UID-GaN) layer 7 have a composition and thickness to allow for stresses to relax, which reduces the incidence of defect formation during the deposition of the different composition layers. As noted, the buffer layer 6 and the undoped GaN or unintentionally doped GaN (UID-GaN) layer 77 may be formed using epitaxial growth. In this manner, the buffer layer 6 is in direct contact with the supporting substrate 5 and the undoped GaN or unintentionally doped GaN (UID-GaN) layer 77 is in direct contact with the buffer layer 6.

Still referring to FIG. 4, the stack 25 further includes a repeating sequence of III-V semiconductor material layers which are deposited for forming the channel regions and two dimensional electron gas (2DEG) regions. In some examples, this sequence includes a sacrificial III-V semiconductor material layer 24. This material layer serves as a place holder that can be subsequently removed in the sequence for forming the functional gate electrode for the gate all around (GAA) architecture gate structure. For example, a first III-V semiconductor material layer is provided in the stack 25 for forming the two dimensional electron gas (2DEG) regions that is identified by reference number 26, and a second III-V semiconductor material layer is provided in the stack 25 for forming the two dimensional electron gas (2DEG) regions that is identified by reference number 27. In the final device, the two dimensional electron gas (2DEG) regions 20 are formed at the interface of these two material layers, i.e., the first and second III-V semiconductor material layers 26, 27 provided in the stack 25 for forming the two dimensional electron gas (2DEG) regions 20.

In one example, the sacrificial III-V material layer 24 is composed of indium, gallium and nitrogen, and can be provided by a indium gallium nitride (InGaN) composition layer. However, in some other embodiments, the sacrificial III-V material layer 24 is composed of indium, gallium and arsenic, and can be provided by an indium gallium arsenic (InGaAs) composition layer.

In one example, the first III-V semiconductor material layer 26 for forming the two dimensional electron gas (2DEG) regions 20 is composed of aluminum, gallium and nitrogen, and in one example is provided by a composition of aluminum gallium nitride (AlGaN). In one example, the second III-V semiconductor material layer 27 for forming the two dimensional electron gas (2DEG) regions 20 is composed of gallium and nitrogen, and in one example is provided by gallium nitride (GaN).

In one embodiment, the sequence of layers in the stack 25 atop the undoped GaN or unintentionally doped GaN (UID-GaN) layer 7 include in the following order a sacrificial III-V semiconductor material layer 24, first III-V semiconductor material layer 26, a second III-V semiconductor material layer 27, and a first III-V semiconductor material layer 26, as depicted in FIG. 4. This sequence is repeated. In the example depicted in FIG. 4, the above described sequence for the stack 25 including the undoped GaN or unintentionally doped GaN (UID-GaN) layer 7 include in the following order a sacrificial III-V semiconductor material layer 24, first III-V semiconductor material layer 26, and the second III-V semiconductor material layer 27 is repeated three times. This only represents one example of the present disclosure, and the methods and structure described herein are not intended to be limited to the only sequences described above.

It is further noted that the compositions are provided for illustrative purposes only. In some embodiments, other III-V compositions may also be selected so long as the sacrificial III-V semiconductor material layer 24, can be removed selectively to the first III-V semiconductor material layer 26, and the second III-V semiconductor material layer 27. For example, other III-V semiconductor materials that can be considered for use with the sacrificial III-V semiconductor material layer 24, the first III-V semiconductor material layer 26, and the second III-V semiconductor material layer 27 may include at least one of aluminum antimonide (AlSb), aluminum arsenide (AlAs), aluminum nitride (AlN), aluminum phosphide (AlP), gallium arsenide (GaAs), gallium phosphide (GaP), indium antimonide (InSb), indium arsenic (InAs), indium nitride (InN), aluminum gallium arsenide (AlGaAs), indium gallium phosphide (InGaP), aluminum indium arsenic (AlInAs), aluminum indium antimonide (AlInSb), gallium arsenide nitride (GaAsN), gallium arsenide antimonide (GaAsSb), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), indium arsenide antimonide phosphide (InArSbP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide aluminum antimonide (GaInNAsSb), gallium indium arsenide antimonide phosphide (GaInAsSbP), and combinations thereof.

The sacrificial III-V semiconductor material layer 24, the first III-V semiconductor material layer 26, and the second III-V semiconductor material layer 27 may each be deposited using a deposition process, such as chemical vapor deposition, e.g, metal organic chemical vapor deposition or plasma enhanced chemical vapor deposition. In some examples, at least one of the sacrificial III-V semiconductor material layer 24, the first III-V semiconductor material layer 26, and the second III-V semiconductor material layer 27 may be deposited using atomic layer deposition (ALD). Each of the sacrificial III-V semiconductor material layer 24, the first III-V semiconductor material layer 26, and the second III-V semiconductor material layer 27 may be epitaxially formed. The thickness of each of the sacrificial III-V semiconductor material layer 24, the first III-V semiconductor material layer 26, and the second III-V semiconductor material layer 27 may be nanoscale, e.g., ranging from 4 nm to 5 nm.

FIGS. 5A-5C illustrate one embodiment of forming fin structures 30 from the stack 25 illustrated in FIG. 4. FIG. 5A is a side cross-sectional view along the channel cross-section of the structure illustrating forming fin structures from the stack depicted in FIG. 4. From a top perspective the cross section depicted in FIG. 5A is taken along a section line identified as A-A in the top down view of the final structure as illustrated in FIG. 1. FIG. 5B is a side cross-sectional view illustrating an across the channel cross-section of the structure depicted in FIG. 5A, and within the gate structure. FIG. 5C is a side cross-sectional view that is parallel to the cross section depicted in FIG. 5B, but it taken from a portion of the device outside the channel and gate structure regions, and through the source/drain regions.

In some embodiments, the fin structures 30 may be formed from the stack 25 using photolithography and etch processes. Specifically, in one example, a photoresist mask is formed overlying the portions of the stack which provides the fin structures 30. The exposed portions of the semiconductor layer that provides the fin structures 30 that are not protected by the photoresist mask are removed using an etch process, .e.g., anisotropic etch process. To provide the photoresist mask, a photoresist layer is first positioned on the semiconductor material that provides the fin structure 30. The photoresist layer may be provided by a blanket layer of photoresist material that is formed utilizing a deposition process such as, e.g., plasma enhanced CVD (PECVD), evaporation or spin-on coating.

The blanket layer of photoresist material is then patterned to provide the photoresist mask utilizing a lithographic process that may include exposing the photoresist material to a pattern of radiation and developing the exposed photoresist material utilizing a resist developer. Following the formation of the photoresist mask, an etching process may remove the unprotected portions of the semiconductor layers in the stack. The etch process may be an anisotropic process, such as reactive ion etch (RIE).

In one embodiment, the etch process may continue through each of the layers of the sacrificial III-V semiconductor material layer 24, the first III-V semiconductor material layer 26, and the second III-V semiconductor material layer 27, wherein the etch process stops on the III-V buffer layer 23.

FIGS. 5A-5C also illustrate forming isolation regions 31, e.g., shallow trench isolation (STI) regions. The isolation regions 31 are formed within the undoped GaN or unintentionally doped GaN (UID-GaN) layer 7 by forming a trench between the fin structures 30 in the undoped GaN or unintentionally doped GaN (UID-GaN) layer 7, and then filling the trench with a deposited dielectric material. One process flow for forming the isolation regions can include a dielectric overfill, followed by a chemical mechanical planarization (CMP) that is terminated on the hardmask of the stacks 25 using end point detection. In a following step, the dielectric may be etched back to the desired level to provide the isolation regions 31. Thereafter, the hardmask which may be present atop the stacks 25 can be removed.

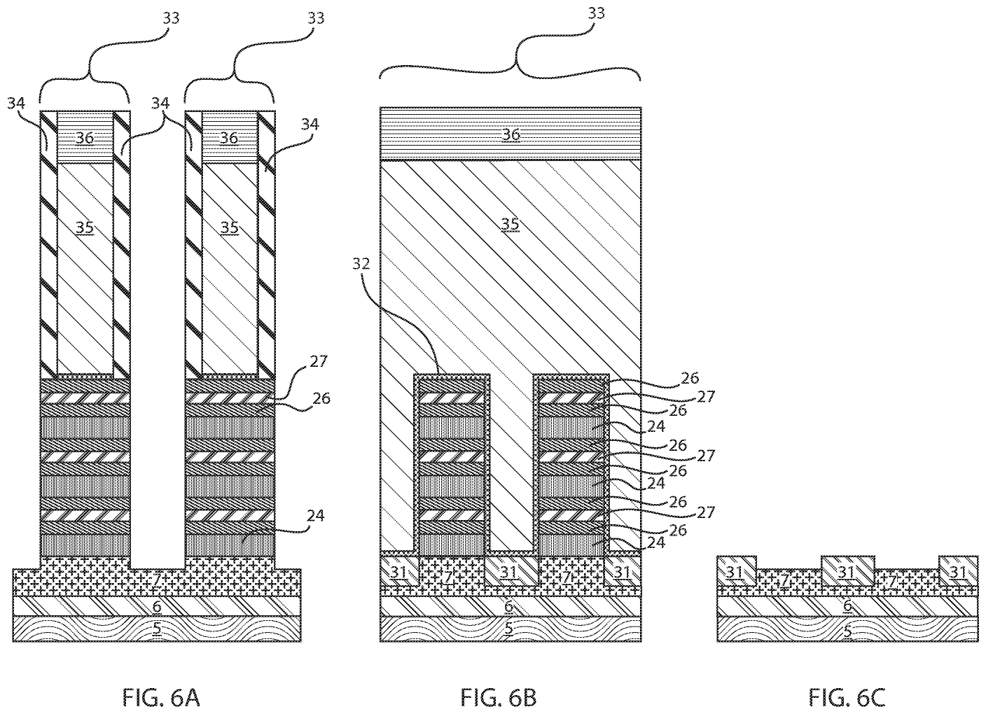

FIGS. 6A-6C illustrate a resultant structure following a process sequence that is applied to the structure depicted in FIGS. 5A-5C that includes forming a dummy oxide layer 32, forming a dummy gate 33 on the dummy oxide layer 32, forming a spacer 34 on the dummy gate, and then performing a fin recess step. The dummy oxide layer 32 may be formed of deposited silicon oxide (SiO₂) or a metal oxide, such as aluminum oxide (AlOₓ (e.g., Al₂O₃). The dummy oxide layer 32 may be deposited using a conformal deposition process. For example, the dummy oxide layer 32 may be formed using chemical vapor deposition methods, such as metal organic chemical vapor deposition or plasma enhanced chemical vapor deposition. In one examples, the dummy oxide layer 32 may also be formed using atomic layer deposition (ALD). The thickness of the dummy oxide layer 32 may be nanoscale, e.g., being less than 5 nm in thickness. In some examples, the dummy oxide layer 32 may be a monolayer. As illustrated in FIG. 6B, the dummy oxide layer 32 is present on the channel region of the structure. However, the dummy oxide layer 32 is not present on the source and drain regions of the structure, as illustrated in FIG. 6C.

Following deposition of the conformal blanket layer of the dummy oxide layer 32, the material for the dummy gate 33 is formed. The dummy gate may be composed of silicon. For example, the dummy gate 33 may be composed of amorphous silicon or polysilicon material. The dummy gate 33 is formed by depositing a material layer for the dummy gate electrode 35, forming a hardmask 36 atop the material layer for the dummy gate electrode 35 that is patterned corresponding to the desired dummy gate geometry; and then etching the material layer for the dummy gate electrode 35 using the hardmask 36. The etch process may be anisotropic. In some embodiments, the etch process is a sequence that also removes exposed portions of the deposited material layer for the dummy oxide layer 32. The etch process may be selective to the upper surface of the stack 25.

Still referring to FIGS. 6A-6C, in a following process sequence, spacers 34 are formed on the sidewalls of the dummy gate 34. The spacer material may comprise a dielectric, such as a nitride, oxide, oxynitride, or a combination thereof. In some embodiments, the spacer material 34 may be a low-k dielectric material, such as SiOC, SiON, SiOCN, SiBCN and combinations thereof. The spacers 34 of a gate structure can be formed using a conformal deposition process, such as plasma enhanced chemical vapor deposition (PECVD) or atomic layer deposition (ALD), that is followed by an etch back process, such as reactive ion etching (RIE).

FIGS. 6A-6C also depict one embodiment of recessing the fin structures 30. Recessing the fin structures 30 may include an anisotropic etch process, such as reactive ion etching, that employs the dummy gate 33 and spacers 34 as an etch mask. As illustrated in FIGS. 6A and 6B, a portion of the fin structure 30 remains in the channel regions of the device, whereas an entirety of the fin structure 30 has been removed from the portions of the structure in which the source and drain regions 10 are subsequently formed.

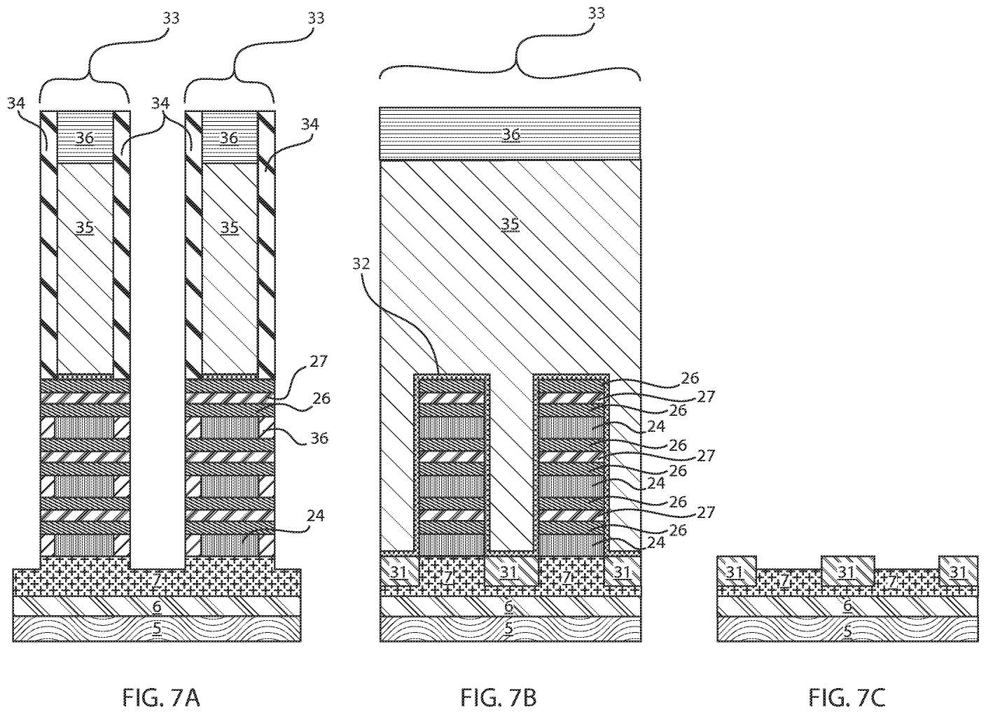

FIGS. 7A-7C illustrate one embodiment of inner spacer 36 formation. The inner spacer 36 supports the layers of the stack 25, i.e., the first III-V semiconductor material layer 26, and the second III-V semiconductor material layer 27, at which the two dimensional electron gas (2DEG) regions are present following removal of the layers of the sacrificial III-V semiconductor material layer 24. Forming the inner spacer 36 may include selective indentation of one of the first and second III-V semiconductor material layers 26, 27; conformal deposition of a dielectric layer for providing the inner spacer 36, and an etchback process for removing at least a portion of the dielectric material for the inner spacer 36 that was not present in the indentation.

In one embodiment, forming the indentation included a selective etch that removed the sidewall material of the sacrificial III-V semiconductor material layer 24. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 10:1 or greater, e.g., 100:1 or greater, or 1000:1 or greater.

In some embodiments, the etch process for forming the indentation removes the sacrificial III-V semiconductor material selectively to the first and second III-V semiconductor material layers 26, 27. The etch process forms a recess between the sequences of the first and second III-V semiconductor material layers 26, 27 that are in direct contact with one another. In this example, the edges of the channel region are recessed under a gate sidewall spacer. The etch process for forming the indentation by removing the sidewall portions of the sacrificial III-V semiconductor material layer 24 may be an anisotropic etch, such as reactive ion etch, plasma gas etch or laser etch. In other embodiments, the etch process for removing the material of the may be an isotropic etch, such as a wet chemical etch or plasma etch.

In a following process step, a conformal deposition is performed of a material layer for providing the inner spacer 36. The term “conformal layer” denotes a layer having a thickness that does not deviate from greater than or less than 30% of an average value for the thickness of the layer. To provide the conformal layer, the dielectric material layer for forming the first spacer 25 may be deposited using atomic layer deposition (ALD) or plasma enhanced chemical vapor deposition (PECVD). The dielectric material is deposited to fill the indentation that was formed in the sidewalls of the sacrificial III-V semiconductor material layer. The inner spacer may be formed of an oxide, nitride or oxynitride material. In some examples, the inner spacer 36 is composed of silicon nitride. In other examples, the inner spacer 36 is composed of silicon oxide.

In some embodiments, the inner spacer material may be a low-k dielectric material, such as SiOC, SiON, SiOCN, SiBCN and combinations thereof.

It is noted that the conformally deposited material layer for the inner spacer 36 is not only formed in the indentation that is formed by removing the sidewall portions of the sacrificial III-V semiconductor material layer 24. The conformally deposited material for the inner spacer 36 is also formed on the sidewalls of the fin structures 30 and spacers 33. To remove the portions of the conformally deposited material layer for the inner spacer 36 that extend from the indentation formed in the sidewall of the sacrificial III-V semiconductor material layer 24, an etch back process is applied. The etch back process may be an isotropic etch. As opposed to an anisotropic etch, an isotropic etch is substantially non-directional. The etch back process may be a timed etch to ensure that the remaining portion of the conformally deposited material is only present in the indentation to provide the inner spacer 36.

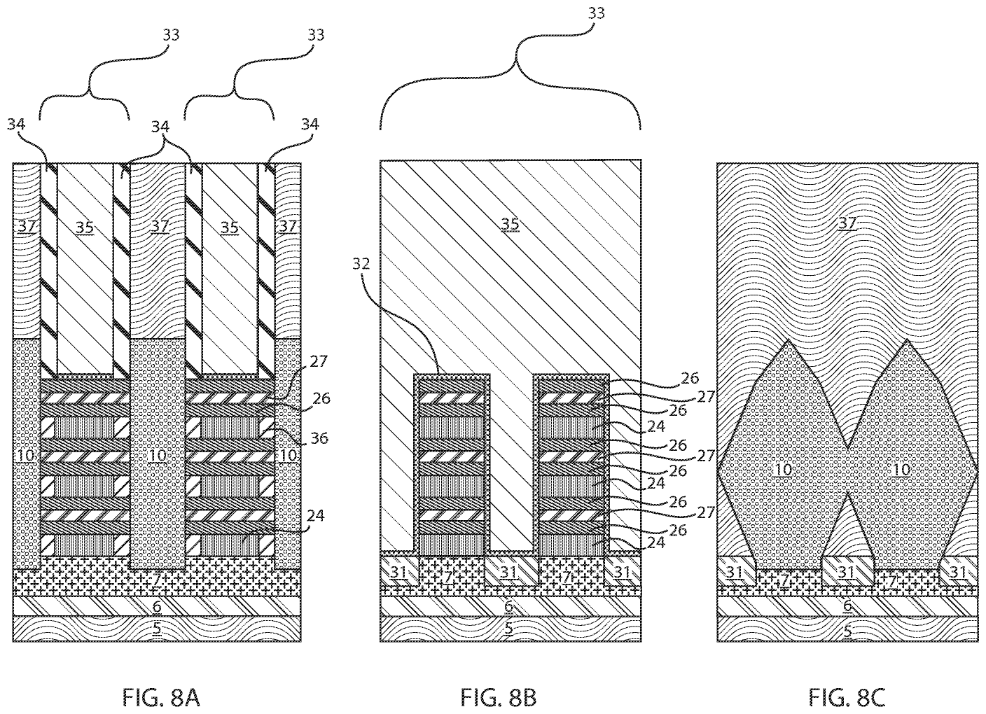

FIGS. 8A-8C also depict one embodiment of forming the source/drain regions 10 from epitaxially grown semiconductor materials. In some embodiments, the epitaxial source and drain region portions 10 may be composed of a III/V semiconductor material. The source and drain region portions 10 are grown on the exposed sidewalls of the semiconductor material of the fin structures using an epitaxial growth or deposition process. The source and drain region portions 10 are also formed on the upper surface of the III-V buffer layer 23. For example, review of FIG. 7C illustrates that along the cross section through the source and drain regions, the upper surface of the III-V buffer layer 23 is exposed. This can serve as a growth surface, i.e., epitaxial growth surface, for the source and drain region portions 10. “Epitaxial growth and/or deposition” means the growth of a semiconductor material on a deposition surface of a semiconductor material, e.g., the exposed surface of the fin structures 15 having the first orientation, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, an epitaxial film deposited on a {100} crystal surface will take on a {100} orientation.

The source/drain regions 10 may be composed of gallium nitride (GaN) that is p-type doped with magnesium (Mg). In some embodiments, the source/drain regions are formed using a chemical vapor deposition (CVD) process, such as metal organic chemical vapor deposition (MOCVD). The p-type dopant, e.g., magnesium (Mg), may be introduced to the source/drain regions 10 using insitu doping. The term “in situ” denotes that the dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses.

In one example, in which the source/drain regions 10 are formed using chemical vapor deposition methods, the source gas for gallium nitride (GaN) may include trimethyl-gallium ((CH₃)₃Ga) for gallium (Ga), and ammonia (NH₃) for nitrogen, wherein the magnesium p-type dopant may be provided by bis-cyclopentadienylmagnesium (Cp₂Mg). Alternatively, the source/drain regions 10 may be formed using molecular beam epitaxy (MBE). The dopant for the epitaxial source and drain region portions 10 that dictates the conductivity type of the epitaxial source and drain region portions 10 is typically present in a concentration ranging from 1×10¹⁵ atoms/cm³ to 1×10²¹ atoms/cm³. Other concentration levels can also be considered.

FIGS. 8A-8C also depict one embodiment of forming an intralevel dielectric layer 37 having an upper surface that is coplanar with the upper surface of the dummy gate structure 33. The intralevel dielectric layer 37 may be selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The interlevel dielectric layer 37 may be deposited by chemical vapor deposition (CVD), physical vapor deposition (PVD), spin on deposition, deposition from solution or a combination thereof. Following deposition, the upper surface of the intralevel dielectric layer 37 may be planarized until coplanar with the upper surface of the sacrificial electrode 35. The planarization process may be provided by chemical mechanical planarization.

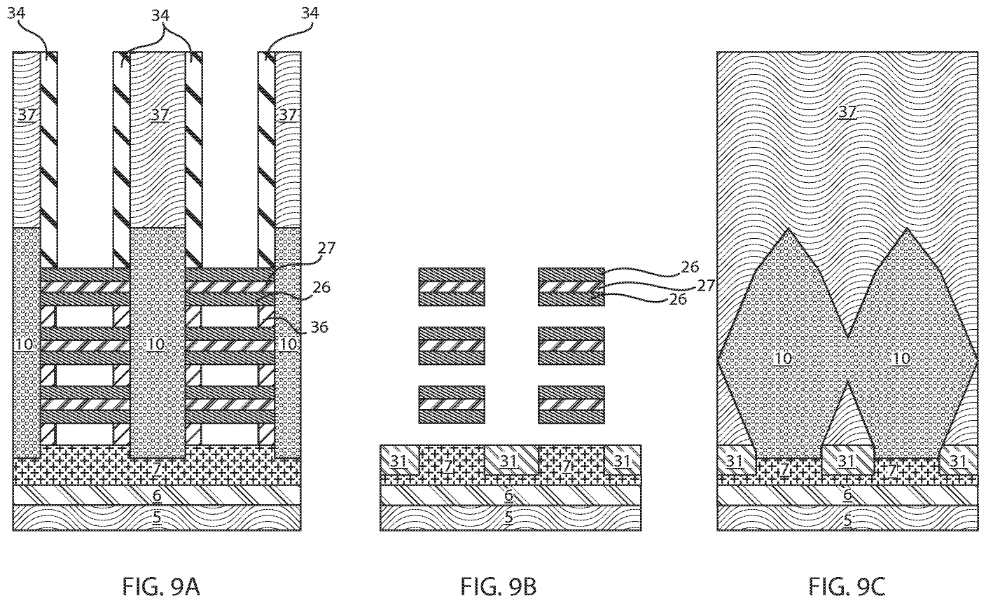

FIGS. 9A-9C depict one embodiment of removing the dummy gate electrode 35 and the dummy oxide layer 32. In a following step, the sacrificial III-V semiconductor material 24 is removed using an etch that is selective to at least the first and second III-V semiconductor material layers 26, 27. In one embodiment, the etch process for removing the sacrificial III-V semiconductor material 24 is also selective to the first and second III-V semiconductor material layers 26, 27. In some embodiments, the sacrificial III-V semiconductor material 24 may be removed by an isotropic etch, such as gas etching, plasma etching or a wet etch.

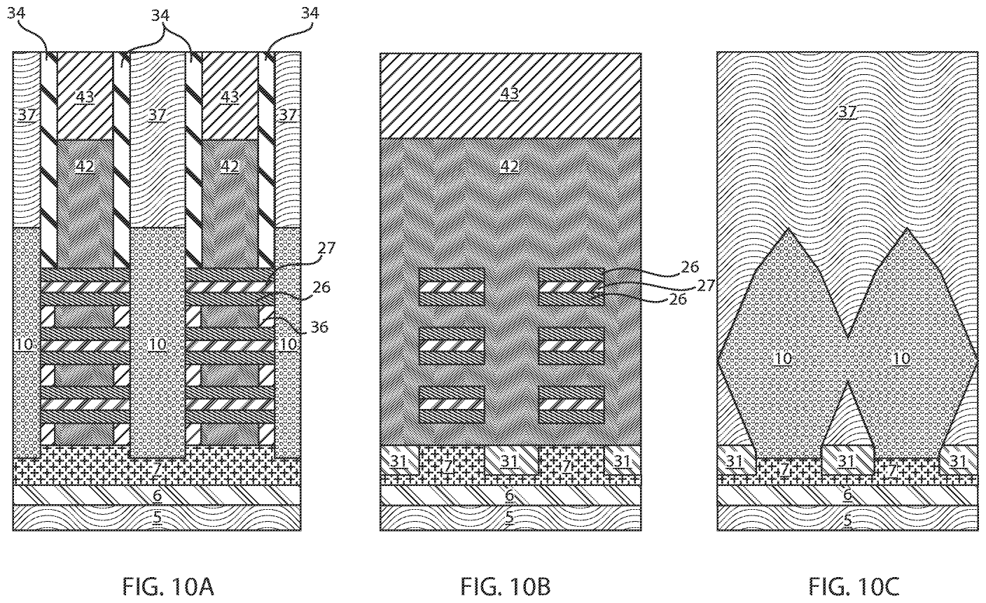

FIGS. 10A-10C depict one embodiment of forming a functional gate structure 40 in the opening that is formed by removing the dummy gate electrode 35, the dummy oxide layer 32 and the sacrificial III-V semiconductor material 24. The functional gate structure 40 is formed wrapping around the remaining portions of the fin structure 30. The “functional gate structure” operates to switch the semiconductor device from an “on” to “off” state, and vice versa. The functional gate structure 40 includes at least one functional gate dielectric and at least one functional gate electrode 42.

The functional gate dielectric may be a high-k dielectric material layer that is formed in direct contact with the channel provided by the first and second III-V semiconductor material layers 26, 27, as well as the two dimensional electron gas (2DEG) regions 20. High-k dielectric materials may have a dielectric constant greater than silicon oxide (SiO₂). For example, high-k dielectrics having a dielectric constant greater than 4.0 at room temperature, e.g., 20° C. to 25° C. and atmospheric pressure, e.g., 1 atm. In one example, the gate dielectric can be aluminum oxide (Al₂O₃). In one embodiment, the high-k dielectric material for the functional gate dielectric 41 is composed of a high-k oxide such as, for example, HfO₂, ZrO₂, Al₂O₃, TiO₂, La₂O₃, SrTiO₃, LaAlO₃, Y₂O₃ and mixtures thereof. Other examples of high-k dielectric materials may include hafnium silicate, hafnium silicon oxynitride or combinations thereof.

In one embodiment, the functional gate dielectric may be deposited by chemical vapor deposition (CVD). Variations of CVD processes suitable for depositing the at least one gate dielectric layer include, but are not limited to, atmospheric pressure chemical vapor deposition (APCVD), low pressure chemical vapor deposition (LPCVD), plasma enhanced chemical vapor deposition (PECVD), metal organic chemical vapor deposition (MOCVD), atomic layer deposition (ALD), and combinations thereof. In other embodiments, the functional gate dielectric 41 is deposited by atomic layer deposition.

The functional gate dielectric can be deposited having a conformal thickness. In one embodiment, the thickness of the high-k dielectric material layer is greater than 0.8 nm. More typically, the high-k dielectric material layer has a thickness ranging from about 1.0 nm to about 6.0 nm.

FIGS. 10A-10C depict depositing a functional gate electrode 42, e.g., a metal gate electrode, in the gate opening atop the functional gate dielectric. In some embodiments, a deposited metal provides the functional gate electrode 42 of a functional gate structure. In some embodiments, polysilicon provides the functional gate electrode 42 of a functional gate structure. The material for the functional gate electrode 42 may be formed using a deposition process. The metal may fill the gate opening. In some embodiments, the metal is formed using a physical vapor deposition (PVD) process, such as sputtering. Examples of sputtering apparatus that may be suitable for depositing the at least one gate conductor include DC diode type systems, radio frequency (RF) sputtering, magnetron sputtering, and ionized metal plasma (IMP) sputtering.

In some embodiments, a dielectric cap structure 43 may be formed atop the functional gate electrode 42.

It is noted that at this point of the process flow, the gate all around (GAA) functional gate structure has been formed. Further, the channel regions include layers of the first and second III-V semiconductor material layers 26, 27 with two dimensional electron gas (2DEG) regions 20 at the interfaces of these semiconductor materials. The process sequence described with reference to FIGS. 4-10C provides the semiconductor devices described above and depicted in FIGS. 1-2B.

FIGS. 2A and 2B illustrate one embodiment of gate all around (GAA) architecture in combination with a fully depleted two dimensional electron gas (2DEG) regions, in which the channel configuration is of a stacked planar two dimensional (2D) electron gas (EG) channel. In some embodiments, the use of the gate all around (GAA) architecture in combination with a fully depleted two dimensional electron gas (2DEG) can improve charge density and gate control.

Referring to FIGS. 1-2B, the method may further include trench contact patterning and etching. FIGS. 1-2B also depict forming source and drain contacts 49 to the source/drain regions 10. Forming the contacts 65 may include forming via openings in the interlevel dielectric 50 to the epitaxial material of the source and drain regions 10, and filling the via openings with metal to provide the contacts 49.

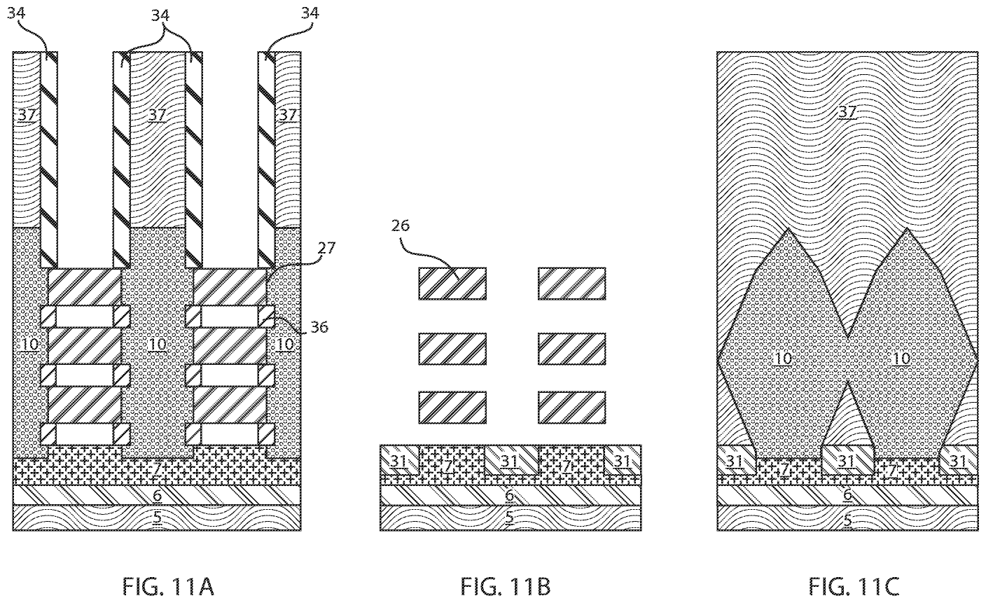

FIGS. 11A-14C depict one embodiment for a method of forming the structures depicted in FIGS. 3A and 3B. FIGS. 3A and 3B depict a semiconductor devie in which the channel configuration is of a wrap around two dimensional (2D) electron gas (EG) channel. FIGS. 11A -11C start an alternative process flow that begins with the structure depicted in FIGS. 9A-9C with the exception of the stacks 25 of semiconductor material include a sequence of a sacrificial layer and a core layer 45. For example, the sacrificial layer may be indium gallium arsenic (InGaAs) or indium gallium nitride (InGaN). The material layers that provide the core layer 45 may be composed of gallium nitride (GaN). This bilayer stack of the sacrificial layer and the core layer 45 is substituted for the stack sequence of the sacrificial III-V semiconductor material layer 24, the first III-V semiconductor material layer 26, the second III-V semiconductor material layer 27, and the first III-V semiconductor material layer 26 that is depicted in FIG. 4

In the embodiment that is depicted in FIGS. 11A-11C, following removal of the dummy gate electrode 35 and the dummy gate oxide 32, the process flow depicted in FIGS. 11A-14C can continue with removing the sacrificial layer selectively to the core layer 45. The sacrificial layer may be removed by a selective etch process, such as an isotropic etch. Examples of isotropic etch processed for removing the sacrificial layer can include a gas etch, plasma etch or wet chemical etch. In one example, removing the sacrificial layer selectively to the core layer 45 provides a plurality of gallium nitride (GaN) suspensions or indium gallium nitride (InGaN) suspensions.

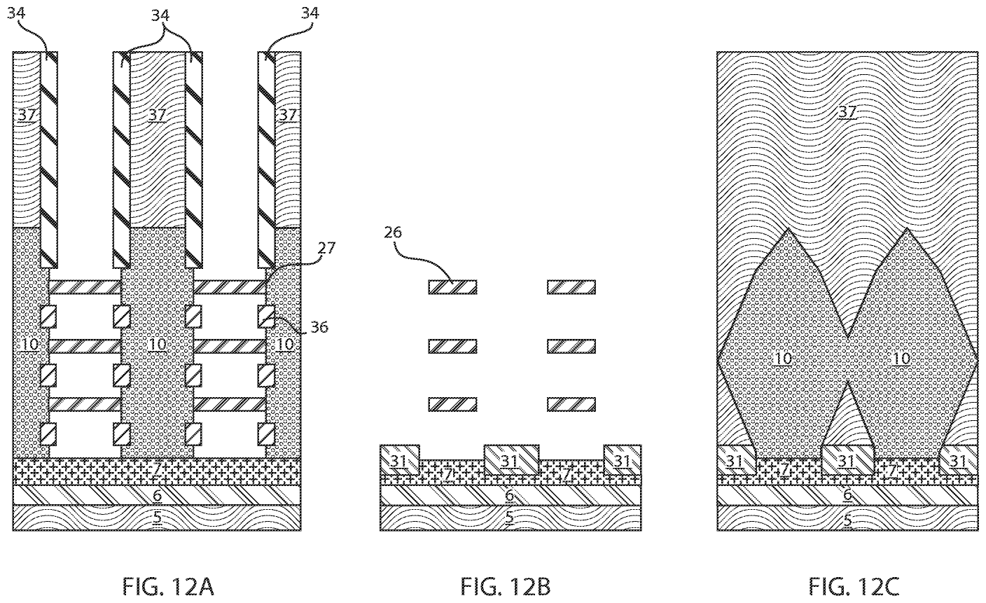

FIGS. 12A-12C illustrate one embodiment of trimming the core layers 45 that remain suspended. In some examples, the composition of the core layer 45 that provides the suspensions of semiconductor material that is processed by the trimming step may be composed of gallium nitride (GaN) or indium gallium nitride (InGaN). The trimming step is an isotropic etch treatment that reduces the thickness of the suspended material, i.e., the suspended core layer 45. The etch process may be a gas etch, plasma etch or wet etch, and the chemistry may be selective to removing the material of the core layer 45 without substantially etching the surrounding material. The reduction in thickness may be on the order of 1 nm to 2 nm. It is noted that this dimension is provided for illustrative purposes only, and is not intended to limit the present disclosure.

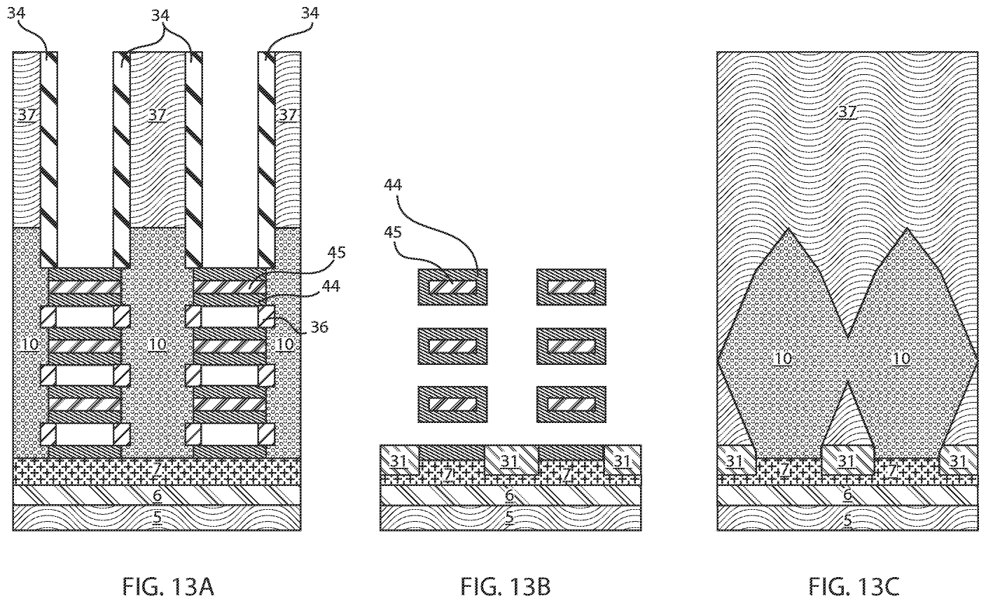

FIGS. 13A-13C illustrate the formation of a cladded epitaxy layer 44 (also referred to as wrap-around III-V semiconductor layer) on the trimmed core layer 45. The cladded epitaxy layer 44 is formed on the exterior surfaces of the core layer 45 and two dimensional (2D) electron gas (EG) regions are formed at the interfaces of the trimmed III-V semiconductor material of the core layer 45 and the III-V semiconductor of the cladded epitaxy layer 44. In one example, the cladded epitaxy layer 44 has a conformal thickness, and in some embodiments can be formed using a chemical vapor deposition (CVD) method, such as metal organic chemical vapor deposition (MOCVD). In some embodiments, the cladded epitaxy layer 44 is composed of a semiconductor material that includes aluminum, gallium, and nitrogen. For example, the cladded epitaxy layer 44 may be composed of aluminum gallium nitride (AlGaN). In some examples, the conformal thickness of the wrap around III-V semiconductor material layer may range from 2 nm to 3 nm.

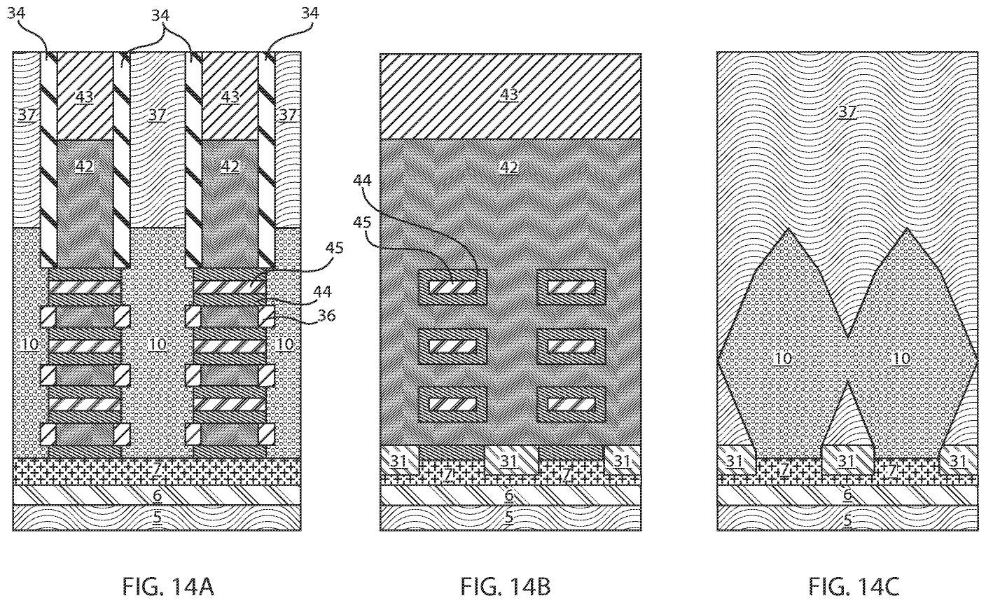

FIGS. 14A-14C depict one embodiment of forming a functional gate structure 40 in the opening illustrated in FIGS. 13A-13C that is formed by removing the dummy gate electrode 35, the dummy oxide layer 32 and the sacrificial III-V semiconductor material 24. The process for forming the functional gate depicted in FIGS. 14A-14C is similar to the process for forming the functional gate that is depicted in FIGS. 10A-10C that was employed for the process flow used for forming the structure illustrated by FIGS. 2A and 2B. Therefore, the description of the structures having reference numbers illustrated in FIGS. 10A-10C is applicable for the structures having the same reference numbers in the FIGS. 13A-13C.

FIGS. 3A and 3B illustrate one embodiment of gate all around (GAA) architecture in combination with a fully depleted two dimensional electron gas (2DEG) regions, in which the channel configuration is of a stacked planar two dimensional (2D) electron gas (EG) channel. In some embodiments, the use of the gate all around (GAA) architecture in combination with a fully depleted two dimensional electron gas (2DEG) can improve charge density and gate control.

Referring to FIGS. 3A-3B, the method may further include trench contact patterning and etching. FIGS. 1-2B also depict forming source and drain contacts 49 to the source/drain regions 10. Forming the contacts 65 may include forming via openings in the interlevel dielectric 50 to the epitaxial material of the source and drain regions 10, and filling the via openings with metal to provide the contacts 49.

The methods and structures that have been described above with reference to FIGS. 1-14C may be employed in any electrical device. For example, the FinFETs that are disclosed herein may be present within electrical devices that employ semiconductors that are present within integrated circuit chips. The integrated circuit chips including the disclosed interconnects may be integrated with other chips, discrete circuit elements, and/or other signal processing devices as part of either (a) an intermediate product, such as a motherboard, or (b) an end product. The end product can be any product that includes integrated circuit chips, including computer products or devices having a display, a keyboard or other input device, and a central processor.

Having described preferred embodiments of a methods and structures for field effect transistor with 2-dimensional electron gas channels that are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor structure comprising:
a channel region comprising at least one channel of at least two III-V semiconductor material layers having a two dimensional electron gas regions at an interface of the at least two III-V semiconductor material layers;
a gate all around (GAA) geometry gate structure present on the channel region; and
source and drain regions on opposing sides of the channel region.

2. The semiconductor structure of claim 1, wherein the source and drain regions are p-type doped.

3. The semiconductor structure of claim 1, wherein the at least one channel is a plurality of vertically stacked channels.

4. The semiconductor structure of claim 1, wherein edges of the channel region are recessed under a gate sidewall spacer.

5. The semiconductor structure of claim 3, wherein the plurality of vertically stacked channels are separated by an inner spacer.

6. The semiconductor structure of claim 1, wherein the at least two III-V semiconductor material layers comprises a stack of a second type III-V semiconductor material layer between two first type III-V semiconductor material layers.

7. The semiconductor structure of claim 5, wherein the first type III-V semiconductor material layers are comprised of aluminum gallium nitride, and the second type III-V semiconductor material layer is comprised of gallium nitride.

8. The semiconductor structure of claim 1, wherein the at least two III-V semiconductor material layers include a core semiconductor layer and a wrap around semiconductor layer that is present on the exterior faces of the core semiconductor layer, the two dimensional (2D) electron gas (EG) channel regions present at interfaces of the core semiconductor layer and the wrap around semiconductor layer.

9. The semiconductor structure of claim 8, wherein the wrap around semiconductor layer is comprised of aluminum gallium nitride, and the core semiconductor layer is comprised of gallium nitride.

10. A semiconductor structure comprising:
a channel region comprising at least one channel of at least two III-V semiconductor material layers having a two dimensional electron gas regions at an interface of the at least two III-V semiconductor material layers, wherein the at least two III-V semiconductor material layers include
a core semiconductor layer and an epitaxial cladding layer that is present on the exterior faces of the core semiconductor layer;
a gate all around (GAA) geometry gate structure present on the channel region; and
source and drain regions on opposing sides of the channel region.

11. The semiconductor structure of claim 10, wherein the source and drain regions are p-type doped.

12. The semiconductor structure of claim 10, wherein the at least one channel is a plurality of vertically stacked channels.

13. The semiconductor structure of claim 10, wherein edges of the channel region are recessed under a gate sidewall spacer.

14. The semiconductor structure of claim 12, wherein the plurality of vertically stacked channels are separated by an inner spacer.

15. A method of forming a semiconductor structure comprising:
forming a stack including a repeating sequence including a sacrificial III-V semiconductor material and at least two channel III-V semiconductor materials that form a two dimensional electron gas region at an interface of the at least two channel III-V semiconductor materials;
forming a replacement gate structure on a channel region of a fin structure including the stack including the repeating sequence including a sacrificial III-V semiconductor material and at least two channel III-V semiconductor materials;
forming III-V source and drain regions on source and drain portions of the fin structure at opposing ends of the channel region;
removing the sacrificial III-V semiconductor material, and
replacing the replacement gate structure with a functional gate structure having a gate all around (GAA) geometry on the at least two channel III-V semiconductor materials having the two dimensional electron gas region at the interface of the at least two channel III-V semiconductor materials.

16. The method of claim 15 further comprising patterning the stack to provide the fin structure using photolithography and etching.

17. The method of claim 15, wherein the III-V source and drain regions are formed using epitaxial growth.

18. The method of claim 15, wherein removing the sacrificial III-V semiconductor material comprises:
a selective etch for recessing the sacrificial III-V semiconductor material relative to the at least two III-V semiconductor material layers to provide a notch underlying an edge of the at least two III-V semiconductor material layers;
filling the notch with an inner spacer; and
removing a remainder of the sacrificial III-V semiconductor material.

19. The method of claim 15, wherein the at least two channel III-V semiconductor materials include a core III-V semiconductor material and a wrap around semiconductor layer.

20. The method of claim 15, wherein a composition for the at least two channel III-V semiconductor materials is selected from the group consisting of gallium nitride, indium gallium nitride, aluminum gallium nitride, and combinations thereof.
